(19) United States
(12) Patent Application Publication
(10) Pub. No.: US 2013/0333310 A1
(43) Pub. Date: Dec. 19, 2013

(54) Modular Structure, Modular Panel To Make Said Modular Structure And Corresponding Method To Make Said Modular Structure

(71) Applicant: MAS S.r.l., San Polo di Piave (IT)

(72) Inventor: Mario Damo, Motta di Livenza (TV) (IT)

(21) Appl. No.: 13/919,009

(22) Filed: Jun. 17, 2013

Related U.S. Application Data
(60) Provisional application No. 61/660,069, filed on Jun. 15, 2012.

(51) Int. Cl. E04C 2/52; H01L 31/042

(52) U.S. Cl. CPC E04C 2/521; H01L 31/042
USPC 52/173.3; 52/220.2; 52/747.1

(57) ABSTRACT

Structure, such as a roof or a wall, comprising a plurality of modular panels (11). Each modular panel (11) has a shell (13) and a filling element (14) coupled with each other and defining at least a compartment (24, 25) for the disposition of a heat-carrying fluid and/or of fluidic and electric connection cables. Connection means are provided between one modular panel (11) and one or more adjacent modular panels (11).

### CROSS-REFERENCE TO RELATED APPLICATIONS

This application claims the benefit under 35 U.S.C. §119(e) of U.S. Provisional Patent Application No. 61/660,069, filed Jun. 15, 2012, the entire disclosure of which is incorporated herein by reference.

### BACKGROUND OF THE INVENTION

1. Field of the Invention

The present invention concerns a structure, such as for example a roof or a wall of a building, of the modular type and consisting of a plurality of panels, functionally and mechanically connected with each other.

The invention also concerns the panel used to make the structure, and to the corresponding method to make the structure.

In particular, the present invention can be applied in the building sector when it is intended to make a closed environment or room, acoustically and/or thermally insulated, possibly having anti-seismic characteristics, and/or inside which significant consumption of electric and/or heat energy is expected, and it is desired to partly use clean energy and/or alternative and/or renewable energy.

2. Description of Related Art

There is a known need to use alternative and/or renewable energy sources, to integrate traditional forms of energy production, above all due to the growing attention to reduce atmospheric pollution caused by the use of said traditional forms, as well as rendering their exploitation less intensive.

In this context, solutions are known which provide to install additional structures on the roofs of buildings, such as for example solar or photovoltaic cells or panels, able to exploit the radiant energy of the sun, in order to generate thermal or electric energy respectively.

In the known solutions, the roof of the buildings normally consists of covering elements, such as tiles for example, or panels, which need to be supported by support structures comprising beams and purlins for example. This has a negative affect on both the times and costs of production of the roofs, which are high, as well as on the complexity of making the roof itself.

One disadvantage consists in the great bulk of the additional structures, which entails a certain complexity and difficulty in integrating them with the part of the roof which is already there.

Another disadvantage is the lack of connection elements between the covering elements of the roof and/or the use of materials with little capacity of absorbing elastic energy, with consequent poor anti-seismic characteristics, which may have to be to improved with additional strategies which are equally burdensome in terms of time and cost.

From the patent application PCT/IB2010/001529 a modular panel is known, to make a roof or a wall of a room, comprising an external shell and an internal shell made of a moldable plastic material. The modular panel integrates energy collection and irradiation means, associated to the external shell, and corresponding energy accumulation means, disposed in the volume defined between the external shell and the internal shell. Means for conditioning the room are associated to the internal shell, and face toward the internal room.

After coupling between said internal and external shells, the known modular panel assumes a structural rigidity which confers self-supporting characteristics, even in the possible presence of plugging and/or completion elements, so as not to require auxiliary support and stiffening means.

However, one disadvantage of the known modular panel consists in the complexity of the presence of two shells to be coupled in the single panel and in the connection system between a plurality of the same panels to form a roof There is also complexity in the disposition of the fluidic and electric connections relating to one or more panels.

This disadvantage causes difficulties in the assembly method of the panels to make the roof. Moreover, this configuration defines a permanent or at least unalterable disposition, of the final roof.

### BRIEF SUMMARY OF THE INVENTION

One purpose of the present invention is to make modular panels for roofs and walls able to incorporate means to exploit alternative and/or renewable energy, the configuration of which is simplified and such as to facilitate the assembly, dismantling and maintenance operations of the roof, reducing to a minimum the auxiliary support elements.

Another purpose of the present invention is to make a modular panel and a corresponding roof which is self supporting, at the same time obtaining the reduction of times and costs of production, as well as guaranteeing great structural solidity and resistance to loads.

Another purpose of the present invention is to optimize operations and interventions of the electric and fluidic equipment, and possibly other types (fiber optics, pipes for alarm systems etc.), reducing times and costs and facilitating the access of maintenance men to the intervention zones.

The Applicant has devised, tested and embodied the present invention to overcome the shortcomings of the state of the art and to obtain these and other purposes and advantages.

The present invention is set forth and characterized in the independent claims, while the dependent claims describe other characteristics of the invention or variants to the main inventive idea.

In accordance with the above purposes, a structure, such as a roof or a wall for example, which overcomes the limits of the state of the art and eliminates the defects present therein, comprises a plurality of modular panels.

Each of the modular panels comprises a shell and a filling element, advantageously but not exclusively made of foamed material. The shell and the filling element define a compartment for the disposition of a heat-carrying fluid and/or fluidic and electric connections.

The structure also has connection means provided between one modular panel and one or more adjacent panels.

According to one feature of the present invention, at least one, advantageously both, of either the shell or the filling element have first apertures suitable to be used in the assembly steps. Moreover, the connection means comprise at least a connection plate cooperating with at least two of the modular panels and comprising second apertures able to be aligned to one or more of the first apertures, so that, by means of suitable attachment means cooperating with the first and second apertures, each connection plate renders at least two of the modular panels solid with each other.

The presence of the connection plate defines a simple and functional configuration, which confers optimal self-supporting characteristics on the structure, facilitating and at the same time speeding up the assembly and dismantling and/or maintenance operations of the structure compared with the solutions of the state of the art.

The connection plate has a profile, a bulk and a weight which have advantages as far as production costs and assembly times of the structure are concerned.

The ease in assembling or dismantling also facilitates possible alterations of the final structure, such as a variation in its size.

According to another feature of the present invention, the attachment means comprise elongated elements, preferably metal, and clamping means acting on the elongated elements to selectively clamp them in the desired positions, achieving a stable connection between the two adjacent panels.

The attachment means and the clamping means constitute elements on which the tension due to the weight of the structure is mainly concentrated.

According to another feature of the present invention, each modular panel, in proximity to each of its corners, has at least an abutment surface able to be taken, at the moment of assembly, in abutment with at least a surface of the connection plate.

The abutment surface defines a zone, in addition to that defined by the attachment means and by the clamping means, which strengthens the clamping of two or more adjacent modular panels. Therefore, the tension due to the weight of the structure is uniformly distributed on said surface, which improves the stability.

According to another feature of the present invention, the first apertures and second apertures are circular holes.

According to another feature of the present invention, the attachment means are hollow inside, so that it is possible to make fluidic and electric internal connections pass inside them.

According to another feature of the invention, the clamping means comprises one or more ring-nuts able to clamp the corresponding attachment means on the connection plate.

According to another feature of the invention, the abutment surfaces comprise an internal abutment surface, parallel to the upper surface of the modular panel, and an external abutment surface, inclined with respect to the internal abutment surface.

This configuration allows the parallel or inclined disposition of two adjacent modular panels with respect to each other and to achieve, as desired, a sloping roof or vaulted roof respectively. Advantageously, in both cases the modular panels to make the roof are the same.

According to another feature of the invention, each of the modular panels comprises internally, in proximity to each of its corners, a plurality of reinforcement fins, which further contribute to distribute the tension due to the weight of the structure.

According to another feature of the invention, the connection plate comprises a closing hole able to couple with a mating stem of a closing stopper.

The closing stopper has the function of sealing and/or covering the intersection zone of the comers of two or more adjacent modular panels.

The connection plate can cooperate with a support structure disposed below the roof

This feature assumes particular importance in the case where the roof is disposed cantilevered and extends for large dimensions, for example in the range of more than 8 m. In this case, part of the tension due to the weight of the roof is distributed along the support structure.

The present invention also concerns a modular panel comprising a shell and a filling element coupled with each other and defining at least a compartment for the disposition of a heat-carrying fluid and/or of fluidic and electric connection cables.

According to one feature of the present invention, at least one of either the shell or the filling element has one or more first apertures able to be aligned to second apertures of a connection plate, the latter able to connect, during use, at least two of the adjacent modular panels.

The present invention also concerns a method to achieve a structure as described above.

According to one feature of the present invention, the method comprises at least a step in which the modular panels are placed adjacent to each other, a subsequent step in which the connection plate is rested on at least two of the modular panels so as to align the second apertures of the connection plate with the first apertures of the corresponding modular panels, a third step in which the attachment elements are housed in the first apertures and in the second apertures aligned with each other, and a fourth step in which the attachment elements are clamped to the connection plate by means of the clamping elements.

### BRIEF DESCRIPTION OF THE SEVERAL VIEWS OF THE DRAWINGS

These and other characteristics of the present invention will become apparent from the following description of some forms of embodiment, given as a non-restrictive example with reference to the attached drawings in which:

FIG. 1 is a perspective view, schematized, of a building comprising a sloping roof according to the present invention;

FIG. 2 is a perspective view, schematized, of a building comprising a vaulted roof according to the present invention;

FIG. 3 is a perspective view of an element of the roof in FIGS. 1 and 2;

FIG. 4 is an exploded view of FIG. 3;

FIG. 5 is a longitudinal section of the element in FIG. 3;

FIG. 6 is an enlarged detail of FIG. 5;

FIG. 7 is a perspective view of the join zone between two elements of FIG. 3;

FIG. 8 is a plan section of FIG. 7;

FIG. 9 is a cross section of FIG. 7;

FIG. 10 is an enlarged detail of FIG. 3;

FIGS. 11 and 12 show one way of connecting two elements in FIG. 3;

FIGS. 13 and 14 show another way of connecting two elements in FIG. 3;

FIG. 15 shows an additional structure of the roof in FIGS. 1 and 2;

FIG. 16 is a cross section of a part of the element in FIG. 3;

FIG. 17 is another cross section of a part of the element in FIG. 3;

FIG. 18 is another cross section of a part of the element in FIG. 3;

FIG. 19 is a cross section of FIG. 7.

### DETAILED DESCRIPTION OF THE INVENTION

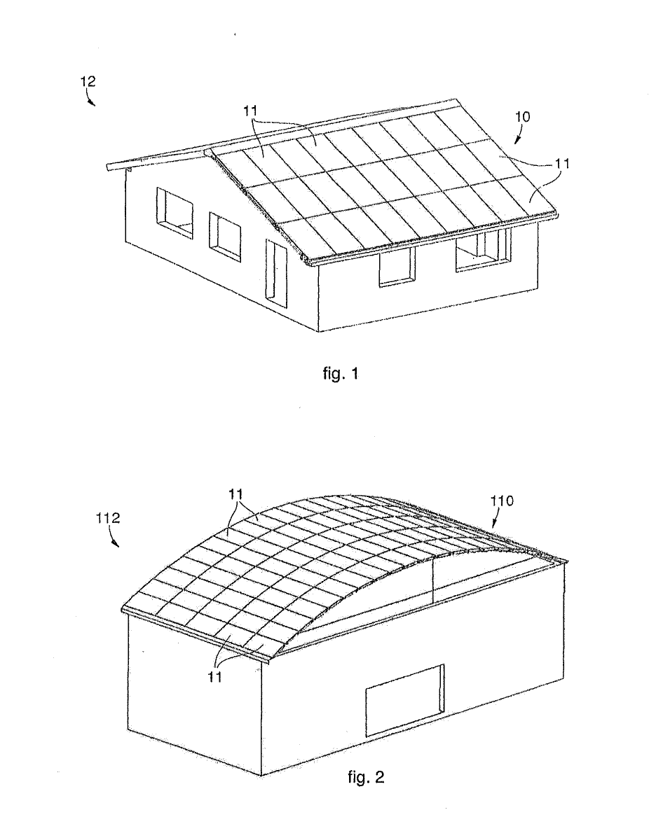

With reference to FIG. 1, a sloping roof 10 is shown, according to the present invention, of a building 12 which in this case can be a house or a small construction of the industrial type.

The roof 10 comprises a plurality of modular panels 11, in this case the same as each other and disposed adjacent, to form a self-supporting, sloping structure.

As well as roofs for houses and small constructions, which are typically sloping, the modular panels 11 can be used to make the roof of bigger buildings 112, where often a self-supporting vaulted roof 110 is used, as shown in FIG. 2.

Both the roofs 10 and 110 comprise modular panels 11 of a rectangular shape which are all the same, but this does not exclude the possibility that they may be made in another geometric shape.

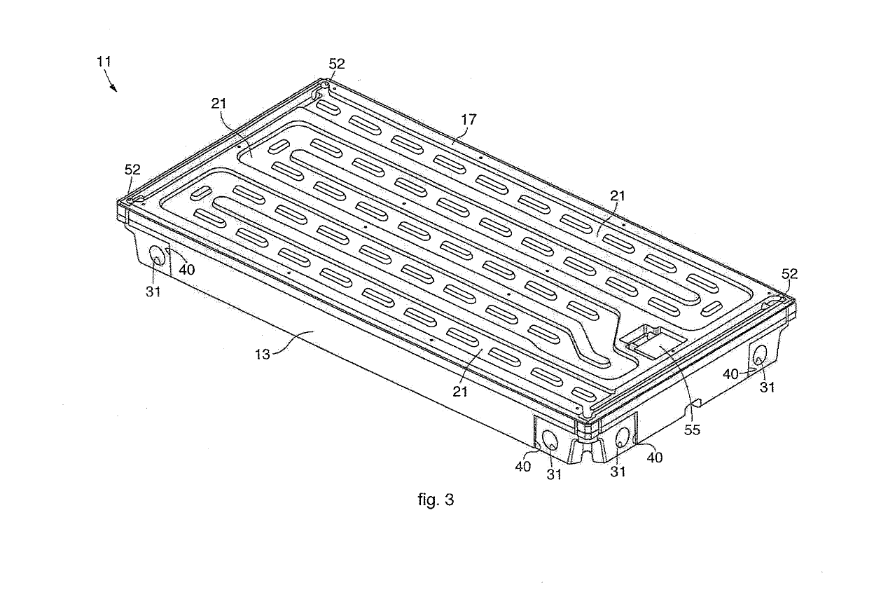

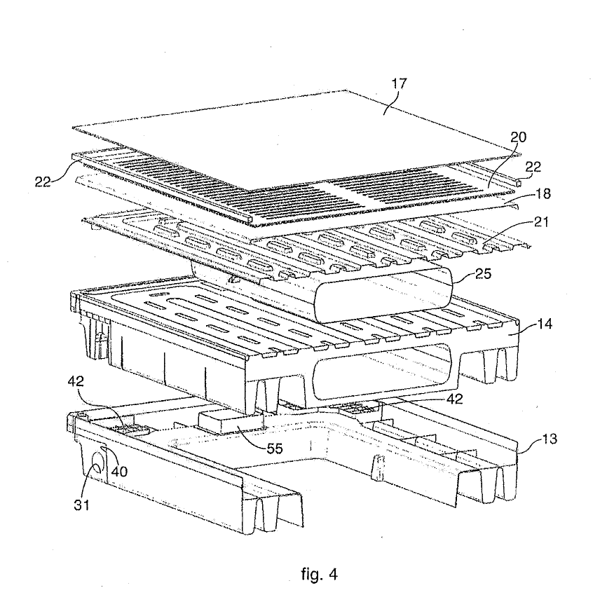

In this case, each modular panel 11 comprises an external shell 13 and a filling element 14 (FIGS. 3 and 4), both made of a moldable plastic material, such as for example a polymer material or similar. At least one of either the external shell 13 or the filling element 14 is advantageously at least partly reinforced with fibers, for example glass or carbon fibers, and/or has reinforcement inserts. In this way, after the coupling of the filling element 14 and the external shell 13, the modular panel 11 assumes structural rigidity which gives it self-supporting characteristics, even considering the possible presence of plugging and/or completion elements as described hereafter.

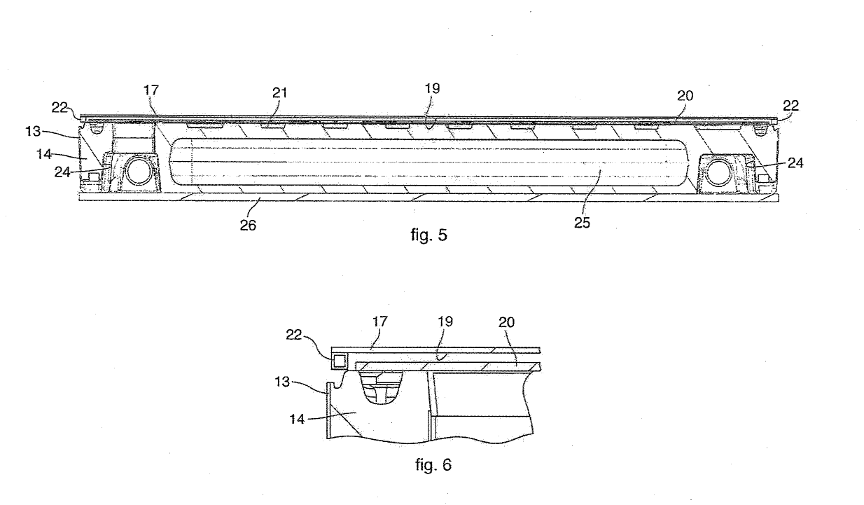

The modular panel also comprises a glass panel 17 and a collecting panel 18, between which a chamber 19 is interposed (FIGS. 5 and 6) inside which, in this case, a photovoltaic panel 20 can be disposed, not shown in FIG. 3. The glass panel 17, together with a frame 22 which acts as an insulating spacer, generates a “greenhouse effect” inside the chamber 19.

The photovoltaic panel 20 is able to transform a part of the solar energy received into electricity, while the rest of the solar energy is converted into thermal energy using the collecting panel 18.

Most of the radiation which strikes the photovoltaic panel 20 reaches the collecting panel 18, the surface of which is black. This increases its temperature and allows to transmit thermal energy to a heat-carrying fluid which flows in a coil-shaped circuit 21 made by molding.

The collecting panel 18 can consist of a metal sheet or of other material, and, in the preferential solution, has a pigmented surface or a coating, for example of ceramic material. This is to capture the radiation and transform it into heat to be transferred to the heat-carrying fluid which flows in the circuit 21, so as to have the greatest possible transfer of energy.

The external shell 13 constitutes the frame of the whole roof 10, 110 and can be made of thermoplastic material, for example.

The filling element 14 is able to contain an internal tank 25, but not necessarily, having the function of containing the heat-carrying fluid.

The external shell 13 and the filling element 14 define a connection compartment 24 to house the necessary fluidic and/or electric links or connections, not shown in the drawings.

A closing panel 26 is disposed in correspondence to the lower part of the modular panel 11 and facing toward the inside of the building 12, 112. The closing panel 26 has both a functional and aesthetic function, since it closes the ceiling of the building 12, 112, contributing to the acoustic insulation and constituting a good flame retardant. Moreover, the configuration of the closing panel 26, which can be covered in a layer of paint as desired, can be removed at any time for maintenance of the roof 10, 110.

There may or may not be an optional photovoltaic panel 20 which is positioned immediately above the collecting panel 18. The heat-carrying fluid circulating in the circuit 21 cools the collecting panel 18 and consequently also the photovoltaic panel 20, increasing the efficiency of the latter.

The glass panel 17, facing toward the outside, is permeable to solar radiations, which hit the photovoltaic panel 20.

The mechanical, hydraulic and electric connections able to support the roof 10, 110 and suitable for the functioning of the modular panel 11 are disposed inside and outside the external shell 13 and the corresponding filling element 14.

Two or more modular panels 11 are kept in position and attached to each other by means of connection plates 28 and attachment elements, in this case hollow cylinders 27, some of which, according to needs, are also used for the passage of the electric and fluidic connections.

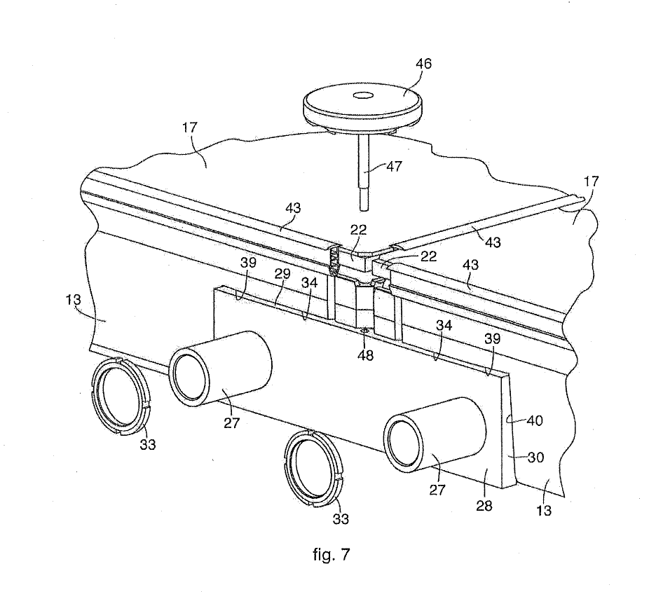

FIG. 7 shows the coupling of two modular panels 11 of the sloping roof 10. This coupling principle can be adopted to make the entire roof 10.

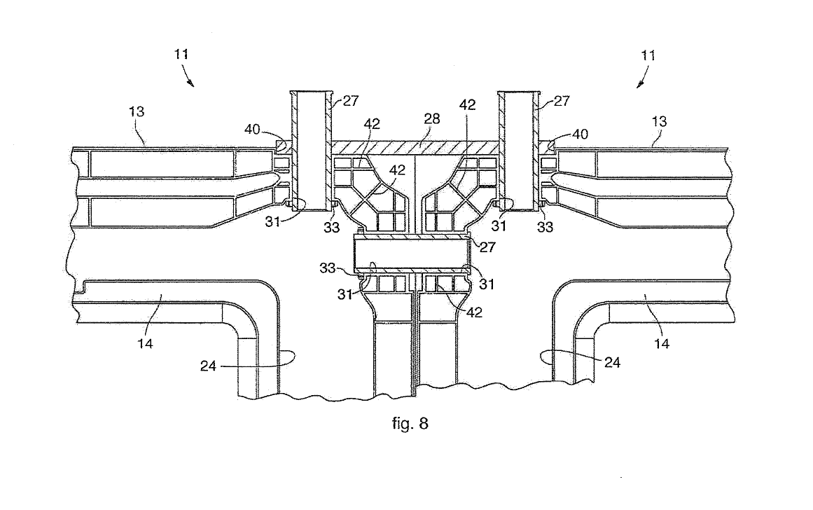

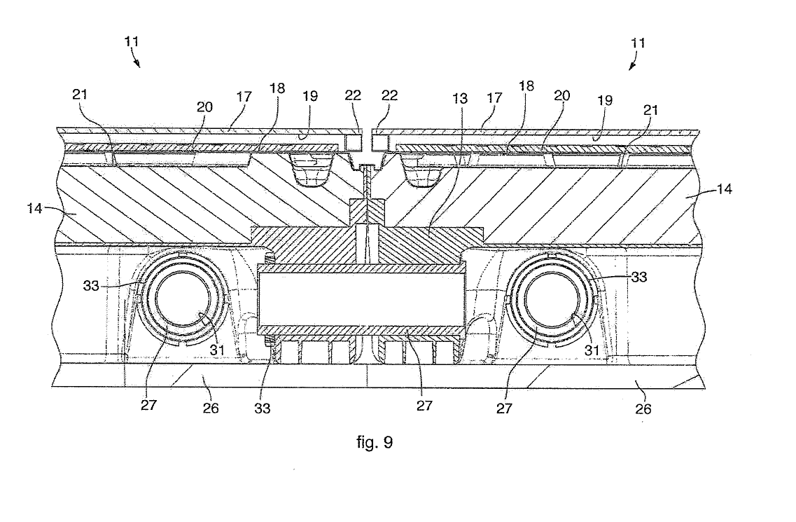

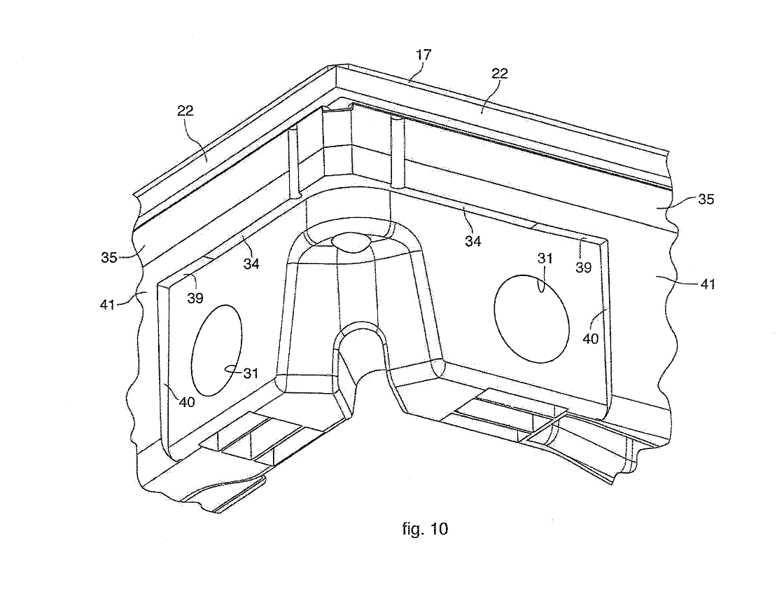

At each of its corners, each modular panel 11 has two first connection holes 31 orthogonal with respect to each other. The disposition of the two modular panels 11 shown in FIGS. 8 and 9 determine two first connection holes 31 parallel to each other and two first connection holes 31 aligned with each other, that is, their longitudinal axis is coincident.

The two modular panels 11 are attached to each other, in the internal apart of the roof 10, by one of the hollow cylinders 27 housed inside the two first connection holes 31 aligned with each other (central part of FIG. 8).

In the external part of the roof 10 the two modular panels 11 are attached to each other using two hollow cylinders 27 and the connection plate 28.

The connection plate 28 comprises two second connection holes 32 which are the same size as the first connection holes 31. The connection plate 28 is positioned so as to align the second connection holes 32 with the first connection holes 31 of the modular panels 11. This alignment allows to house the two hollow cylinders 27.

Four modular panels 11 can therefore be kept coupled in the corresponding corner by four hollow cylinders 27 and a connection plate 28, thus defining an optimum attachment and in any case allowing them to be dismantled at any time, if necessary.

In the case of the drawing, the corners of the two modular panels 11 are attached to each other in two zones, that is, in the internal par by means of a hollow cylinder 27, and in the external part, by means of two hollow cylinders 27 and a connection plate 28. Therefore, in a specular manner, two other modular panels 11, attached to the first using the same method, can be brought together.

On the roof 10, each modular panel 11 is surrounded along its entire perimeter by identical modular panels 11 and attached at least by hollow cylinders 27 and ring-nuts 33.

In this case, each hollow cylinder 27 is held in position by a clamping ring 33, or ring-nut, having an internal threading able to couple with a mating external threading of the hollow cylinder 27.

In the case shown in the drawing, both the hollow cylinders 27 cooperating with the connection plate 28, and also those disposed perpendicularly, are used, as well as for attachment, also for the possible passage of the fluidic and/or electric connections.

The connection plate 28 has a rectangular plan profile and comprises a larger lateral surface 29 and two smaller lateral surfaces 30.

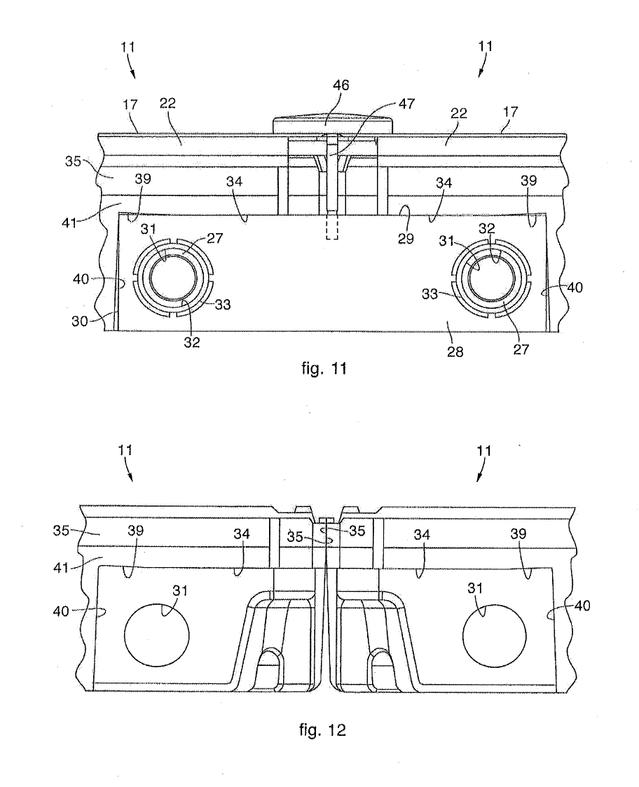

In the case of a sloping roof 10, the larger lateral surface 29 abuts with an internal abutment surface 34, made on the modular panel 11 and parallel to the glass panel 17. Moreover, upper lateral walls 35, orthogonal to the glass panel 17, of the modular panels 11 abut with respect to each other. In this way, the modular panels 11 of the roof 10 are aligned and parallel with respect to each other (FIGS. 11 and 12).

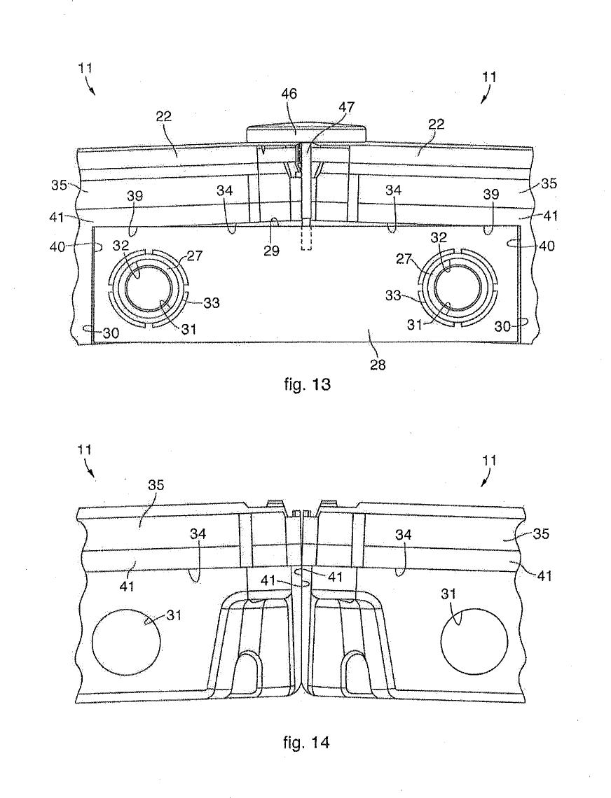

In the case of a vaulted roof 110, the larger lateral surface 29 abuts with a pair of external abutment surfaces 39, inclined by a few degrees with respect to the glass panel 17, and therefore also with respect to the larger lateral surface 29, and with two lateral abutment surfaces 40, orthogonal to the respective external abutment surfaces 40. The external abutment surfaces 39 and the lateral abutment surfaces 40 are both made on one side of the modular panel 11. Moreover, lower lateral walls 41, parallel to the external abutment surfaces 40, are able to abut with each other. In this way, each modular panel 11 is inclined with respect to the adjacent modular panel 11 (FIGS. 13 and 14).

To facilitate comprehension, particularly to display the surfaces in contact, in FIGS. 12 and 14 the connection plate 28 is not shown.

In correspondence to its corners, each modular panel 11 comprises a plurality of reinforcement fins 42 inside it. This solution guarantees a uniform distribution of the tension, that is, the weight of the roof 10, 110, preventing the tension from concentrating in limited zones and consequently preventing the collapse of the structure.

According to the configuration described, the tension passes from one modular panel 11 to another passing through the hollow cylinders 27, the abutment surfaces 34, 39, 40 and the fins 42.

A packing 43 is disposed between one modular panel 11 and the adjacent one, with the purpose of preventing possible leakages of fluid along the perimeter of the modular panel 11.

In correspondence to the intersection of the corners of the modular panels 11 a stopper 46 is disposed, comprising a threaded stem 47 able to be screwed into a corresponding closing hole 48 suitably threaded and made in the connection plate 28. The stopper 46 contributes to the sealing action defined by the packings 43 along the edges of the modular panels 11.

The attachment method described confers on the roof 10, 110 a facility and a reduction in the number of elements to assemble it.

According to structural simulations carried out by the Applicant, the modular panels 11 according to the present invention are self-supporting indicatively for structures up to 8 m in width and/or length.

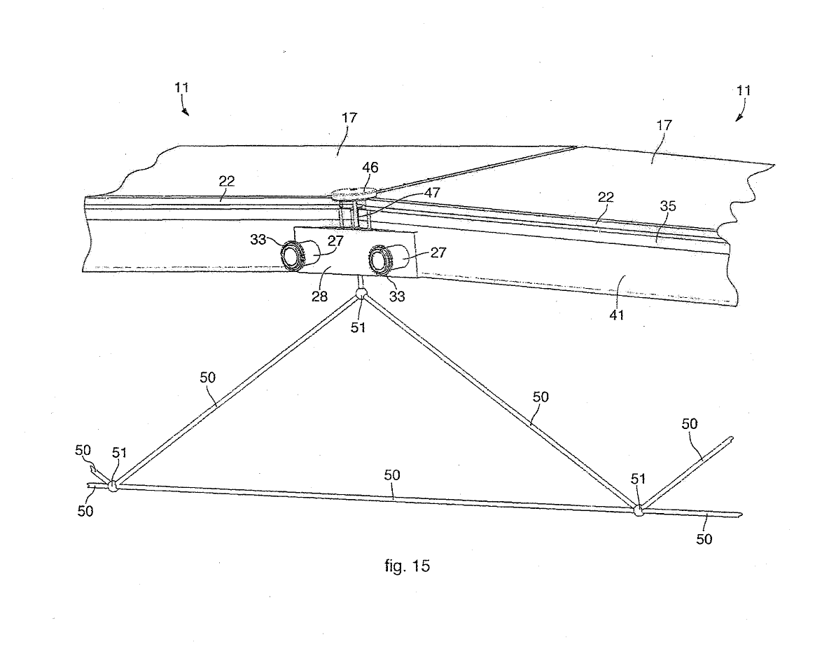

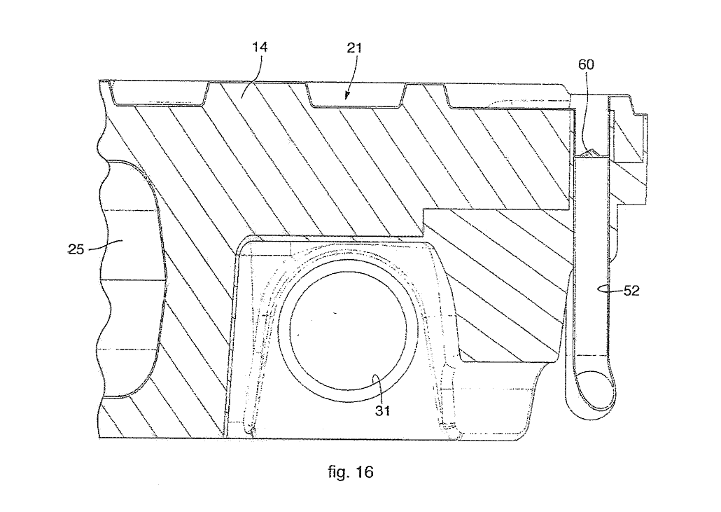

For larger sizes, it is necessary to use further support structures, such as a plurality of beams 50 for example, connected to each other in points called nodes 51 to form a support grid disposed below the roof 10, 110, as schematically shown in FIG. 15. In this way, the roof 10, 110 acquires solidity in that most of the tension passes through the beams 50.

As we said, under the collecting panel 18 there is the circuit 21 and the connection compartment 24 inside which there is the heat-carrying fluid.

Each modular panel 11 comprises a plurality of connection pipes 52 for the heat-carrying fluid, as for example in correspondence to the four corners of the modular panel 11 itself. Before the roof 10, 110 is made, the connection pipes 52 are obstructed by an obstruction screen 60, selectively removable, in a known way or not, depending on the circuit to be defined.

According to the invention, therefore, the circuits advantageously assume a very flexible configuration, highlighting the double function of the hollow cylinders 27, which function both as an attachment element and also as passage elements for the connections.

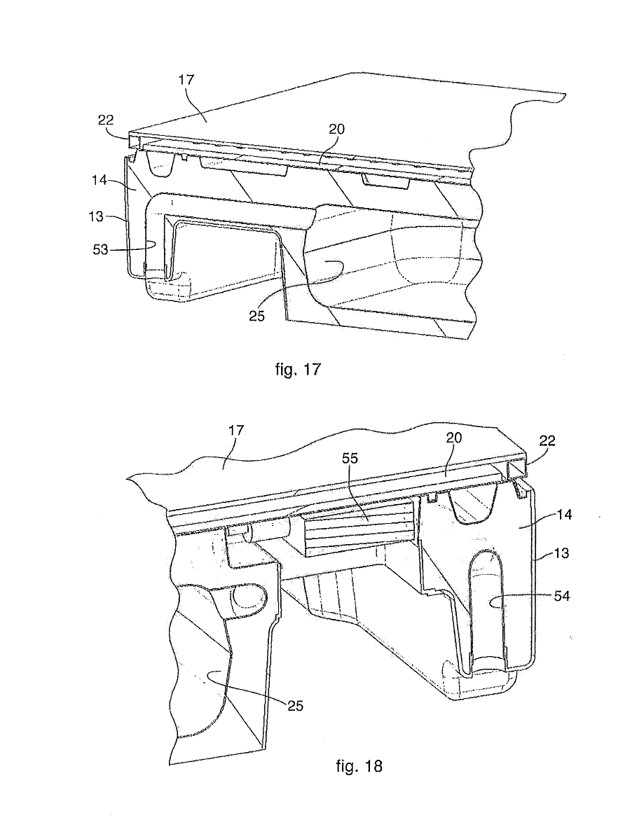

The internal tank 25 of each modular panel 11 cooperates with an inlet pipe 53 (FIG. 17) and with an outlet pipe 54 (FIG. 18) in correspondence to the center line of the shorter side of the modular panel 11. The pipes 53, 54 can be suitable, in a known way, to connect the internal tanks 25 of several modular panels 11. It should be noted that the outlet pipe 54 follows a path having more curves than that followed by the inlet pipe 53, because of the presence of a control unit 55 of the photovoltaic panel 20. In this way the heat-carrying fluid can circulate, and therefore be renewed, between the different internal tanks 25 of the modular panels 11.

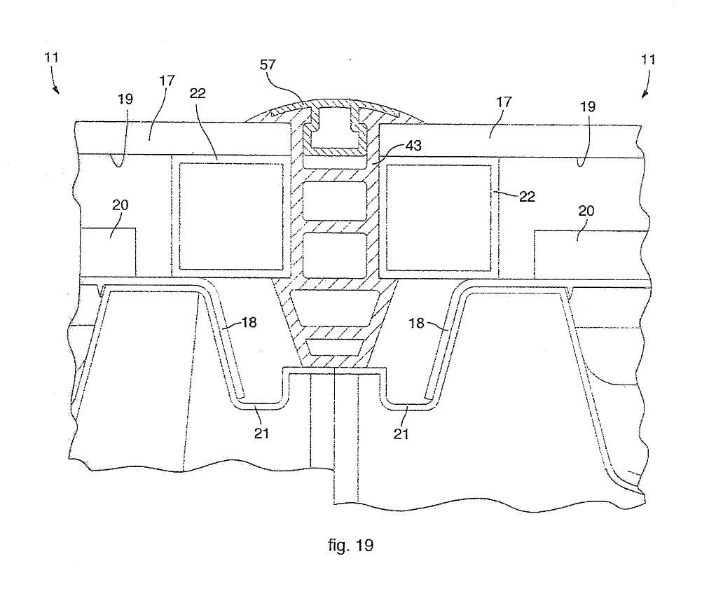

Along each edge of the modular panel 11 the packing 43 is disposed, made mainly of rubber, which cooperates with two modular panels 11 (FIG. 19). The packing 43 comprises an aluminum insert, having the function of compressing the rubber to optimize the seal, but it can be made of any other rigid material.

It is clear that modifications and/or additions of parts may be made to the roof 10, 110 as described heretofore, without departing from the field and scope of the present invention.

For example, the photovoltaic panel 20 may not be present.

It is also clear that, although the present invention has been described with reference to some specific examples, a person of skill in the art shall certainly be able to achieve many other equivalent forms of roof 10, 110, having the characteristics as set forth in the claims and hence all coming within the field of protection defined thereby.

It will be appreciated by those skilled in the art that changes could be made to the embodiments described above without departing from the broad inventive concept thereof. It is understood, therefore, that this invention is not limited to the particular embodiments disclosed, but it is intended to cover modifications within the spirit and scope of the present invention as defined by the appended claims.

1. A structure, such as a roof or a wall, comprising a plurality of modular panels, each modular panel having a shell and a filling element, said shell and said filling element being coupled with each other and defining at least a compartment for the disposition of a heat-carrying fluid and/or of fluidic and electric connection cables, connection means being provided between one modular panel and one or more adjacent modular panels, wherein at least one of either said shell or said filling element has one or more first apertures, and wherein said connection means comprise at least a connection plate cooperating with at least two of said modular panels and comprising second apertures able to be aligned to one or more of said first apertures, so that, by means of attachment means cooperating with said first apertures and said second apertures, said connection plate renders at least two of said modular panels solid with each other.

2. The structure as in claim 1, wherein said attachment means comprise elongated elements, preferably metal, and clamping means acting on said elongated elements to clamp them selectively and in the desired positions.

3. The structure as in claim 2, wherein, in proximity to each of its corners, each modular panel has at least an abutment surface able to be taken, at the moment of assembly, to abut with at least one surface of said connection plate.

4. The structure as in claim 1, wherein said first apertures and said second apertures are circular holes.

5. The structure as in claim 1, wherein said attachment means are internally hollow, so that it is possible to make fluidic and/or electric connections pass inside them.

6. The structure as in any claim 2, wherein said clamping means comprise one or more clamping ring-nuts able to clamp the corresponding attachment mean at least on said connection plate.

7. The structure as in claim 3, wherein said abutment surfaces comprise an internal abutment surface parallel to the upper surface of said modular panel, and an external abutment surface inclined with respect to said internal abutment surface, so that two adjacent modular panels are selectively parallel with respect to each other or inclined with respect to each other.

8. The structure as in claim 1, wherein each of said modular panels comprises, at least in proximity to each of its corners, a plurality of reinforcement fins, so as to uniformly distribute the tension due to the weight of said structure.

9. The structure as in claim 1, wherein said connection plate comprises a threaded closing hole able to couple with a mating threaded stem of a closing stopper, said stopper being suitable to cover and seal an intersection of corners of two or more of said modular panels.

10. A modular panel comprising a shell and a filling element coupled with each other and defining at least a compartment for the disposition of a heat-carrying fluid and/or fluidic and electric connection cables, wherein at least one of either said shell or said filling element has one or more first apertures able to be aligned to second apertures of a connection plat, the latter able to connect, during use, at least two of said adjacent, modular panels with each other.

11. The modular panel as in claim 10, wherein the panel further comprises a glass panel and a collecting panel defining a chamber between them.

12. The modular panel as in claim 11, wherein there is a photovoltaic panel in said chamber.

13. A method to make a structure as in claim 1, comprising at least a step in which said modular panels are put adjacent to each other, a subsequent step in which said connection plate is rested on at least two of said modular panels so as to align said second apertures of the connection plate with said first apertures of the corresponding modular panels, a third step in which said attachment elements are housed in said first apertures and said second apertures aligned with respect to each other, a fourth step in which said attachment elements are clamped to the connection plate by means of said clamping elements.

14. The structure as in claim 1, wherein, in proximity to each of its corners, each modular panel has at least an abutment surface able to be taken, at the moment of assembly, to abut with at least one surface of said connection plate.
